(19) United States
(12) Patent Application Publication
(10) Pub. No.: US 2024/0154044 A1
(43) Pub. Date: May 9, 2024

(54) SCHOTTKY BARRIER DIODE

(71) Applicant: ROHM CO., LTD., KYOTO-SHI (JP)

(72) Inventors: AIKO MIYAZAKI, KYOTO-SHI (JP); TAKAHIRO ARAKAWA, KYOTO-SHI (JP); TOMOYUKI KAWAKAMI, KYOTO-SHI (JP); SATOSHI KOBAYASHI, KYOTO-SHI (JP)

(21) Appl. No.: 18/499,824

(22) Filed: Nov. 1, 2023

(30) Foreign Application Priority Data
Nov. 8, 2022 (JP) 2022-178599

(51) Int. Cl. H01L 29/872; H01L 29/417

(52) U.S. Cl. CPC H01L 29/872; H01L 29/417

(57) ABSTRACT

The present disclosure provides a Schottky barrier diode. The Schottky barrier diode includes: a semiconductor substrate of a first conductivity type; a semiconductor layer of the first conductivity type and having a region of the first conductivity type and an impurity region of the first conductivity type; a first electrode layer; a second electrode layer; a first external terminal electrically connected to the first electrode layer; and a second external terminal electrically connected to the second electrode layer. The first electrode layer includes a first base portion, a first extending portion and a second extending portion. The second electrode layer includes a second base portion and a third extending portion located between the first extending portion and the second extending portion in a second direction.

### TECHNICAL FIELD

The present disclosure relates to a Schottky barrier diode.

### BACKGROUND

Patent document 1 discloses an example of a conventional Schottky barrier diode. The Schottky barrier diode disclosed by the document includes a semiconductor substrate of a first conductivity type, a semiconductor layer of the first conductivity type, a first electrode layer, a second electrode layer, a first external terminal and a second external terminal. The semiconductor layer of the first conductivity type is stacked on the semiconductor substrate of the first conductivity type. The semiconductor layer of the first conductivity type includes a region of the first conductivity type and an impurity region of the first conductivity type. The first electrode layer and the region of the first conductivity type form a Schottky junction in between. The second electrode layer and the impurity region of the first conductivity type form an ohmic contact in between.

### PRIOR ART DOCUMENT

### Patent publication

Patent document 1: Japan Patent Publication No. 7013200

### BRIEF DESCRIPTION OF THE DRAWINGS

FIG. 1 is a perspective view of a Schottky barrier diode according to a first embodiment of the present disclosure.

FIG. 2 is a plan view of a Schottky barrier diode according to the first embodiment of the present disclosure.

FIG. 3 is a partial plan view of a Schottky barrier diode according to the first embodiment of the present disclosure.

FIG. 4 is a cross-sectional view taken along a section line IV-IV in FIG. 2.

FIG. 5 is a cross-sectional view taken along a section line V-V in FIG. 2.

FIG. 6 is a cross-sectional view taken along a section line VI-VI in FIG. 2.

FIG. 7 is a cross-sectional view taken along a section line VII-VII in FIG. 2.

FIG. 8 is a cross-sectional view taken along a section line VIII-VIII in FIG. 2.

FIG. 9 is a cross-sectional view taken along a section line IX-IX in FIG. 2.

FIG. 10 is a plan view of a Schottky barrier diode of a first variation example according to the first embodiment of the present disclosure.

FIG. 11 is a partial plan view of a Schottky barrier diode of the first variation example according to the first embodiment of the present disclosure.

FIG. 12 is a plan view of a Schottky barrier diode of a second variation example according to the first embodiment of the present disclosure.

FIG. 13 is a partial plan view of a Schottky barrier diode of the second variation example according to the first embodiment of the present disclosure.

FIG. 14 is a plan view of a Schottky barrier diode according to a second embodiment of the present disclosure.

FIG. 15 is a partial plan view of a Schottky barrier diode according to the second embodiment of the present disclosure.

### DETAILED DESCRIPTION OF THE EMBODIMENTS

Details of the preferred embodiments of the present disclosure are specifically described with reference to the accompanying drawings below.

The terms “first”, “second” and “third” used in the present disclosure are for identification purposes, and are not construed as sequencing the targets.

In the present disclosure, expressions “an object A formed at an object B” and “an object A formed on/over an object B” include “an object A directly formed at an object B”, and “another object placed between an object A and an object B, and the object A formed at the object B”, unless otherwise specified. Similarly, expressions “an object A arranged at an object B” and “an object A arranged on/over an object B” include “an object A directly arranged at an object B”, and “another object placed between an object A and an object B, and the object A arranged at the object B”, unless otherwise specified. Similarly, an expression “an object A located on an object B” includes “an object A in contact with an object B, and the object A located on/over the object B”, and “another object placed between an object A and an object B, and the object A located on/over the object B”, unless otherwise specified. Moreover, an expression “an object A overlapping an object B when viewed in a direction” includes “an object A completely overlapping an object B” and “an object A partially overlapping an object B”, unless otherwise specified. Moreover, in the present disclosure, an expression “a surface A facing (one side or the other side of) a direction B” is not limited to being a situation where the surface A being at 90° relative to the direction B, but also includes a situation where the surface A is inclined relative to the direction B.

### First Embodiment

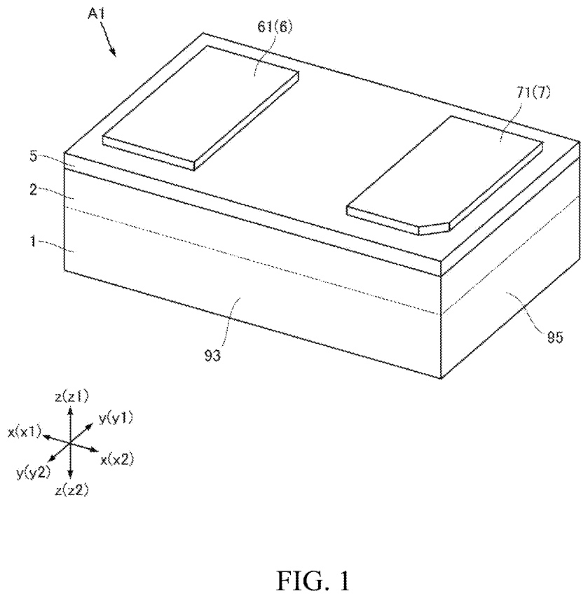

FIG. 1 to FIG. 9 show a Schottky barrier diode according to the first embodiment of the present disclosure. A Schottky barrier diode A1 of this embodiment includes a semiconductor substrate 1 of a first conductivity type, a semiconductor layer 2 of the first conductivity type, a first electrode layer 3, a second electrode layer 4, an insulation layer 5, a first external terminal 6 and a second external terminal 7.

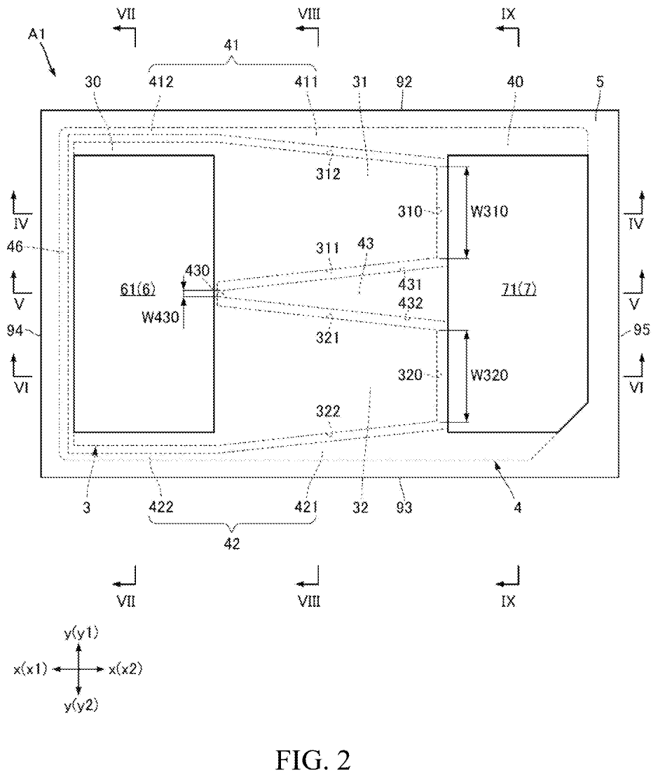

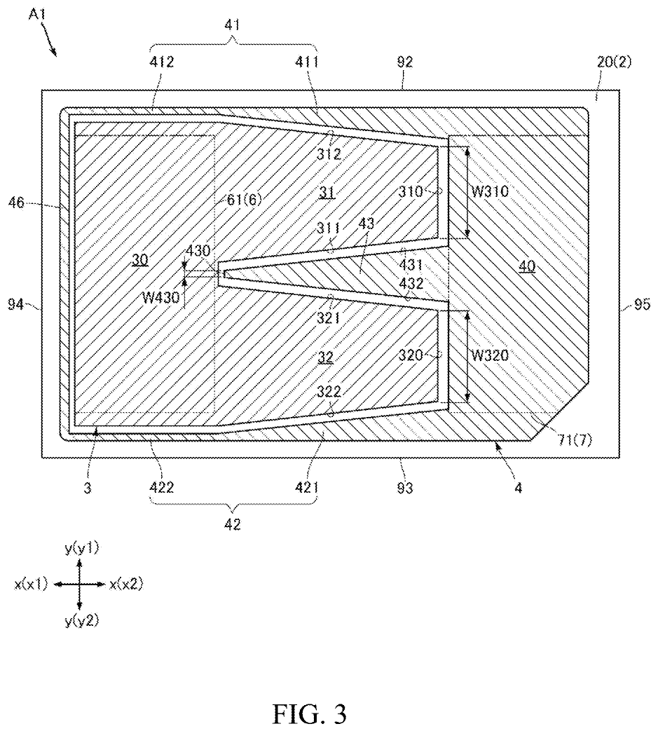

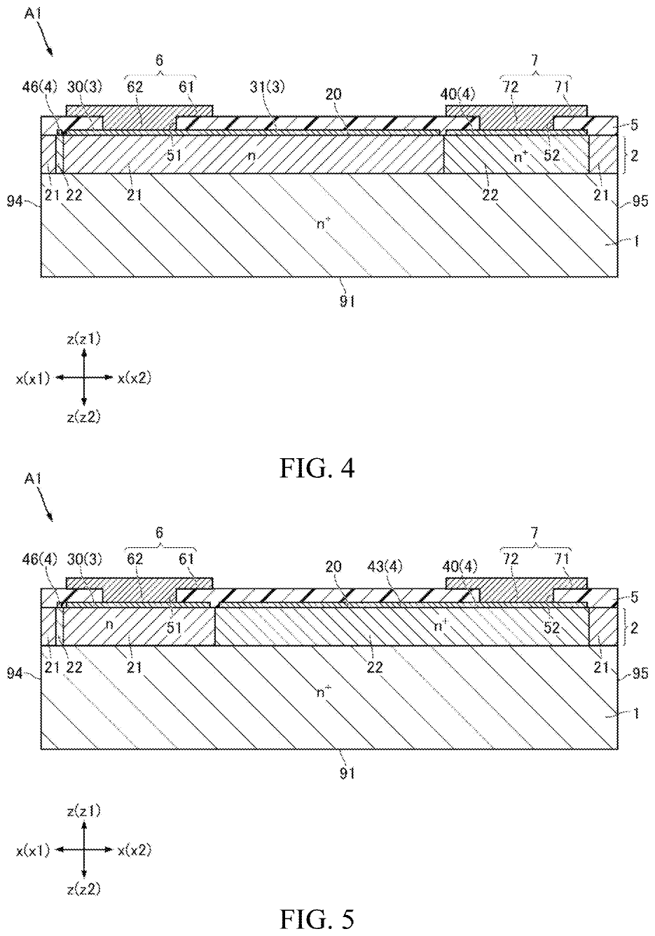

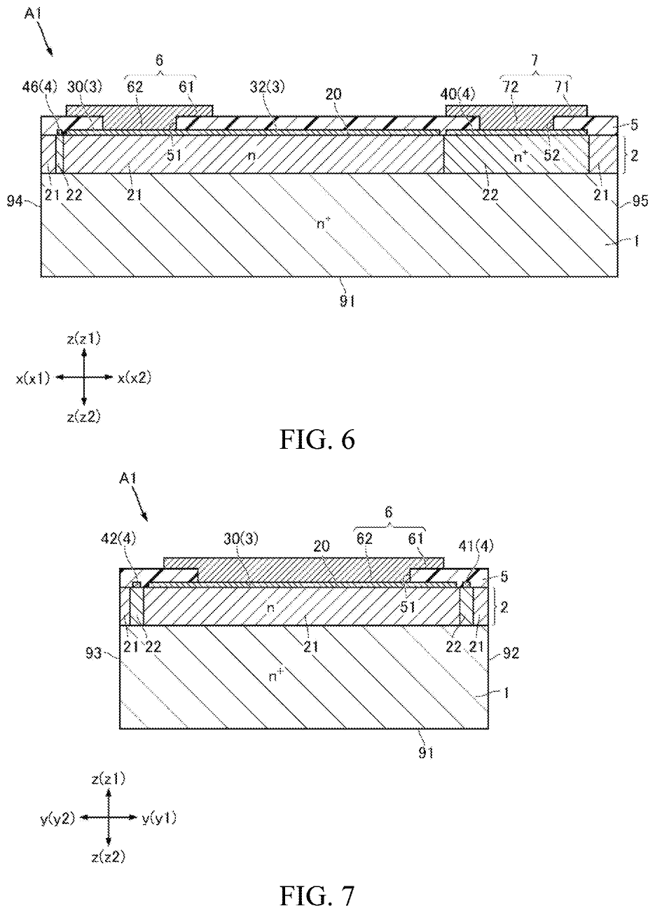

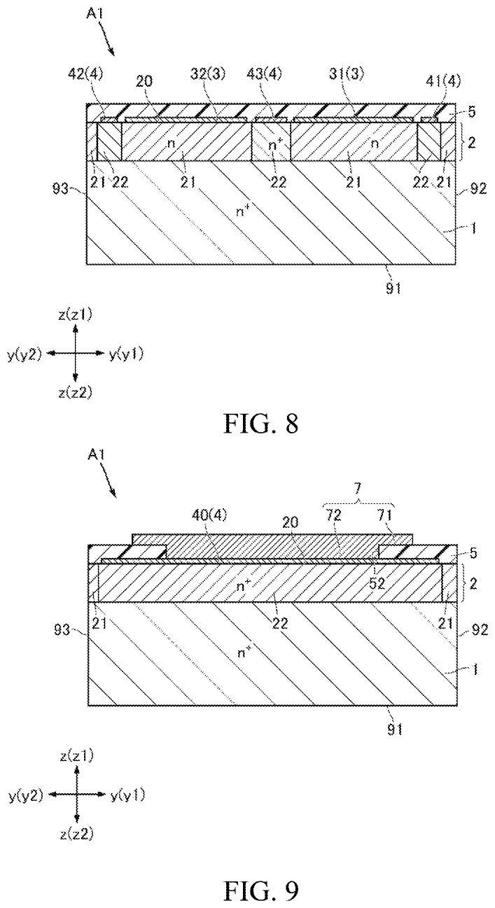

FIG. 1 shows a perspective view of the Schottky barrier diode A1. FIG. 2 shows a plan view of the Schottky barrier diode A1. FIG. 3 shows a partial plan view of the Schottky barrier diode A1. FIG. 4 shows a cross-sectional view taken along a section line IV-IV in FIG. 2. FIG. 5 shows a cross-sectional view taken along a section line V-V in FIG. 2. FIG. 6 shows a cross-sectional view taken along a section line VI-VI in FIG. 2. FIG. 7 shows a cross-sectional view taken along a section line VII-VII in FIG. 2. FIG. 8 shows a cross-sectional view taken along a section line VIII-VIII in FIG. 2. FIG. 9 shows a cross-sectional view taken along a section line IX-IX in FIG. 2. Moreover, in FIG. 3, for better understanding, the insulation layer 5 is omitted, and shading lines are added to the first electrode layer 3 and the second electrode layer 4, and imaginary lines are used to represent the first external terminal 6 and the second external terminal 7. In addition, FIG. 4 to FIG. 8 are cross-sectional views to schematically represent the Schottky barrier diode A1, and configuration details of the various parts can be appropriately implemented by, for example, various generally known structures.

In these drawings, a thickness direction of the present disclosure is defined as a thickness direction z. A first side along the thickness direction z is referred to as a side z1, and a second side along the z direction opposite to the first side is referred to a side z2. Moreover, a direction perpendicular to the thickness direction z is defined as a first direction x. A first side along the first direction x is referred to as a side x1, and a second side along the first direction x opposite to the side x1 is referred to a side x2. Moreover, a direction perpendicular to the thickness direction z and the first direction x is defined as a second direction y. A first side along the second direction y is referred to as a side y1, and a second side opposite to the side y1 along the direction y is referred to a side y2.

The Schottky barrier diode A1 is, for example, cuboid in shape. The size of the Schottky barrier diode A1 is not specifically defined; for example, the size along the first direction x can be 1.6 mm or more and 3.0 mm or less, the size along the second direction y can be 0.8 mm or more and 2.0 mm or less, and the size along the thickness direction z can be 50 μm or more and 400 μm or less.

### Semiconductor Substrate 1 of First Conductivity Type

The semiconductor substrate 1 of the first conductivity type is a layer as a base of the Schottky barrier diode A1, and directly or indirectly refers to the semiconductor layer 2 of the first conductivity type, the first electrode layer 3, the second electrode layer 4, the insulation layer 5, the first external terminal 6 and the second external terminal 7. The thickness of the semiconductor substrate 1 of the first conductivity type along the thickness direction z is not specifically defined, and can be, for example, 50 μm or more and 400 μm or less.

The semiconductor substrate 1 of the first conductivity type can specifically be, for example, an n⁺-type semiconductor substrate. The semiconductor substrate 1 of the first conductivity type can also include an n⁺-type silicon substrate. The semiconductor substrate 1 of the first conductivity type forms a high-concentration and low-resistance region having a relatively high n-type impurity concentration. The resistivity of the semiconductor substrate 1 of the first conductive type can be 1.0 mΩ·cm or more and 5.0 mΩ·cm or less (for example, about 3.0 mΩ·cm).

### Semiconductor Layer 2 of First Conductivity Type

As shown in FIG. 1 and FIG. 4 to FIG. 9, the semiconductor layer 2 of the first conductivity type is stacked on the semiconductor substrate 1 of the first conductivity type on the side z1 along the thickness direction z of the semiconductor substrate 1 of the first conductivity type. The thickness of the semiconductor layer 2 of the first conductivity type along the thickness direction z is not specifically defined, and can be, for example, 2.0 μm or more and 5.0 μm or less.

The semiconductor layer 2 of the first conductivity type can specifically be, for example, an n-type epitaxial layer. The semiconductor layer 2 of the first conductivity type is a silicon film layer stacked on the semiconductor substrate 1 of the first conductivity type by means of epitaxial growth.

The semiconductor layer 2 of the first conductivity type has a main surface 20. The main surface 20 is a surface facing the side z1 along the thickness direction z, and is a flat surface in the example shown in the drawings.

The semiconductor layer 2 of the first conductivity type includes a region 21 of the first conductivity type and an impurity region 22 of the first conductivity type. The region 21 of the first conductivity type is formed as a low-concentration and high-resistance region having an n-type impurity concentration lower than the n-type impurity concentration of the semiconductor substrate 1 of the first conductive type. The resistivity of the region 21 of the first conductive type can be 0.4 Ω·cm or more and 1.0 Ω·cm or less (for example, about 0.7 Ω·cm).

The impurity region 22 of the first conductivity type is formed by introducing an n-type impurity into a portion of an epitaxially grown silicon semiconductor layer. The impurity region 22 of the first conductivity type has an n-type impurity concentration higher than the n-type impurity concentration of the region 21 of the first conductive type. The impurity region 22 of the first conductivity type is formed as a high-concentration and low-resistance region having a relatively high n-type impurity concentration.

In the semiconductor layer 2 of the first conductivity type, the region 21 of the first conductivity type and the impurity region 22 of the first conductivity type are formed as regions separated from each other when viewed along the thickness direction z. The various positions, shapes and sizes become positions, shapes and sizes corresponding to the shapes of the first electrode layer 3 and the second electrode layer 4 described below.

### First Electrode Layer 3

As shown in FIG. 3 to FIG. 8, the first electrode layer 3 is formed on the main surface 20 of the semiconductor layer 2 of first conductivity type. The first electrode layer 3 and the region 21 of the first conductivity type form a Schottky junction in between. The material or layer structure of the first electrode layer 3 is not specifically defined. In this embodiment, the first electrode layer 3 can include, for example, a lower layer stacked on the region 21 of the first conductivity type (the main surface 20) and an upper layer stacked on the lower layer. The lower layer can include metal such as Mo (molybdenum), Pt (platinum), Pd (palladium), Ni (nickel) or Ti (titanium), or an alloy of the above. For example, the lower layer includes Ti and thus functions as a barrier layer. The upper layer includes metal such as aluminum (Al) or copper (Cu), or can include an Al—Cu-containing alloy or Al—Si—Cu-containing alloy.

As shown in FIG. 2 and FIG. 3, the first electrode layer 3 includes a first base portion 30, a first extending portion 31 and a second extending portion 32.

The first base portion 30 is located on the side x1 along the first direction x, and overlaps the first external terminal 6 when viewing along the thickness direction z. In the example shown in the drawings, the first base portion 30 overlaps the entirety of the first external terminal 6 when viewing along the thickness direction z. The first base portion 30 is not defined with a specific shape, and is rectangular in shape in the example shown in the drawings.

The first extending portion 31 extends from the first base portion 30 toward the side x2 along the first direction x. The first extending portion 31 is not defined with a specific size, and can have a size of, for example, 150 μm or more and 800 μm or less, along the first direction x. In the example shown in the drawings, the first extending portion 31 is located on the side y1 along the second direction y. The first extending portion 31 has a first end edge 310, a first side edge 311 and a second side edge 312.

The first end edge 310 is an end edge on the side x2 along the first direction x. In the example shown in the drawings, the first end edge 310 is a straight line along the second direction y. The first end edge 310 is opposite to a second base portion 40 of the second electrode layer 4 described below. The first side edge 311 is a side edge on the side y2 along the second direction y. The second side edge 312 is a side edge on the side y1 along the second direction y.

The first extending portion 31 is not defined with a specific shape, and in the example shown in the drawings, has a tapered shape that becomes smaller as a distance between the first side edge 311 and the second side edge 312 along the second direction y becomes smaller when further away from the first base portion 30 along the first direction x (closer to the side x2 from the side x1). The first side edge 311 and the second side edge 312 are inclined with respect to the first direction x. The angle of inclination of the first side edge 311 and the second side edge 312 can be 1° or more and 16° or less.

The second extending portion 32 extends from the first base portion 30 toward the side x2 along the first direction x. The second extending portion 32 is not defined with a specific size, and can have a size of, for example, 150 μm or more and 800 μm or less, along the first direction x. In the example shown in the drawings, the second extending portion 32 is located on the side y2 along the second direction y. That is to say, the first extending portion 31 and the second extending portion 32 are arranged along the second direction y. The second extending portion 32 has a second end edge 320, a third side edge 321 and a fourth side edge 322.

The second end edge 320 is an end edge on the side x2 along the first direction x. In the example shown in the drawings, the second end edge 320 is a straight line along the second direction y. The second end edge 320 is opposite to the second base portion 40 of the second electrode layer 4 described below. The third side edge 321 is a side edge on the side y1 along the second direction y. The fourth side edge 322 is a side edge on the side y2 along the second direction y.

The second extending portion 32 is not defined with a specific shape, and in the example shown in the drawings, has a tapered shape that becomes smaller as a distance between the third side edge 321 and the fourth side edge 322 along the second direction y becomes smaller when further away from the first base portion 30 along the first direction x (closer to the side x2 from the side x1). The third side edge 321 and the fourth side edge 322 are inclined with respect to the first direction x. The angle of inclination of the third side edge 321 and the fourth side edge 322 can be 1° or more and 16° or less.

Moreover, for example, a protection ring region (omitted from the drawings) including a semiconductor of a second conductivity type (p-type semiconductor) can also be provided on a portion of a surface layer of the region 21 of the first conductivity type that forms the main surface 20. The protection ring region forms a shape conforming to an outer periphery of the first electrode layer 3 when viewing along the thickness direction z. By forming the protection ring, an electric field possibly generated at an outer periphery of a region of the Schottky junction between the region 21 of the first conductivity type and the first electrode layer 3 can be alleviated, hence improving a withstand voltage of the Schottky barrier diode A1.

### Second Electrode Layer 4

As shown in FIG. 3 to FIG. 9, the second electrode layer 4 is formed on the main surface 20 of the semiconductor layer 2 of the first conductivity type. The second electrode layer 4 and the impurity region 22 of the first conductivity type form an ohmic contact in between. The material or layer structure of the second electrode layer 4 is not specifically defined. In this embodiment, the second electrode layer 4 can be formed together with the first electrode layer 3 in a same step, and can include, for example, a lower layer stacked on the impurity region 22 of the first conductivity type (the main surface 20) and an upper layer stacked on the lower layer. The lower layer can include metal such as Mo (molybdenum), Pt (platinum), Pd (palladium), Ni (nickel) or Ti (titanium), or an alloy of the above. For example, the lower layer includes Ti and thus functions as a barrier layer. The upper layer includes metal such as aluminum (Al) or copper (Cu), or can include an Al—Cu-containing alloy or Al—Si—Cu-containing alloy.

As shown in FIG. 2 and FIG. 3, the second electrode layer 4 includes the second base portion 40, a third extending portion 43, a first lateral extending portion 41, a second lateral extending portion 42 and a connecting portion 46.

The second base portion 40 is located on the side x2 along the first direction x, and overlaps the second external terminal 7 when viewing along the thickness direction z. In the example shown in the drawings, the second base portion 40 overlaps the entirety of the second external terminal 7 when viewing along the thickness direction z. The second base portion 40 is not defined with a specific shape, and in the example shown in the drawings, is shaped similar to rectangular which is a shape having a sloped side consistent with a sloped side of the second external terminal 7 when viewing along the thickness direction z.

The third extending portion 43 extends from the second base portion 40 toward the side x1 along the first direction x. The third extending portion 43 is not defined with a specific size, and can have a size of, for example, 150 μm or more and 800 μm or less, along the first direction x. The third extending portion 43 is located between the first extending portion 31 and the second extending portion 32 along the second direction y. The third extending portion 43 has a third end edge 430, a fifth side edge 431 and a sixth side edge 432.

The third end edge 430 is an end edge on the side x1 along the first direction x. In the example shown in the drawings, the third end edge 430 is a straight line along the second direction y. The third end edge 430 is opposite to the first base portion 30 of the first electrode layer 3. The fifth side edge 431 is a side edge on the side y1 along the second direction y, and is opposite to the first side edge 311. The sixth side edge 432 is a side edge on the side y2 along the second direction y, and is opposite to the third side edge 321.

The third extending portion 43 is not defined with a specific shape, and in the example shown in the drawings, has a tapered shape that becomes smaller as a distance between the fifth side edge 431 and the sixth side edge 432 along the second direction y becomes smaller when further away from the second base portion 40 along the first direction x (closer to the side x1 from the side x2). The fifth side edge 431 and the sixth side edge 432 are inclined with respect to the first direction x. The angle of inclination of the fifth side edge 431 and the sixth side edge 432 can be 1° or more and 16° or less.

In this embodiment, a width W430 which is the size of the third end edge 430 along the second direction y is less than a width W310 which is the size of the first end edge 310 along the second direction y and a width W320 which is the size of the second end edge 320 along the second direction y. The width W430 can be between 1 μm or more and 330 μm or less. The width W310 and the width W320 can be between 70 μm or more and 500 μm or less.

The first lateral extending portion 41 extends from an end of the second base portion 40 on the side y1 along the second direction y toward the side x1 along the first direction x. In the example shown in the drawings, the first lateral extending portion 41 has a first tapered portion 411 and a first parallel portion 412.

The first tapered portion 411 is a part connected with the second base portion 40, and is formed in a region overlapping the first extending portion 31, the second extending portion 32 and the third extending portion 43 when viewing along the second direction y. The first tapered portion 411 has a tapered shape that becomes smaller along the second direction y when further away from the second base portion 40 along the first direction x (closer to the side x1 from the side x2). In the example shown in the drawings, an end edge of the first tapered portion 411 on the side y1 along the second direction y is parallel to the first direction x, and an end edge on the side y2 inclines with respect to the second direction y. The angle of inclination of the end edge on the side y2 can be 1° or more and 16° or less.

The first parallel portion 412 extends from the first tapered portion 411 toward the side x1 along the first direction x. The first parallel portion 412 is formed in a region overlapping the first base portion 30 when viewing along the second direction y. In the example shown in the drawings, the size of the first parallel portion 412 along the second direction y is fixed.

The second lateral extending portion 42 extends from an end of the second base portion 40 on the side y2 along the second direction y toward the side x1 along the first direction x. In the example shown in the drawings, the second lateral extending portion 42 has a second tapered portion 421 and a second parallel portion 422.

The second tapered portion 421 is a part connected with the second base portion 40, and is formed in a region overlapping the first extending portion 31, the second extending portion 32 and the third extending portion 43 when viewing along the second direction y. The second tapered portion 421 has a tapered shape that becomes smaller along the second direction y when further away from the second base portion 40 along the first direction x (closer to the side x1 from the side x2). In the example shown in the drawings, an end edge of the second tapered portion 421 on the side y2 along the second direction y is parallel to the first direction x, and an end edge on the side y1 inclines with respect to the second direction y. The angle of inclination of the end edge on the side y1 can be 1° or more and 16° or less.

Moreover, similar to the example shown in the drawings, the first side edge 311, the second side edge 312, the third side edge 321, the fourth side edge 322, the fifth side edge 431, the sixth side edge 432, the end edge of the first tapered portion 411 on the side y2 and the end edge of the second tapered portion 421 on the side y1 can have equal angles of inclination with respect to the first direction x. Accordingly, a configuration in which the first extending portion 31, the second extending portion 32, the third extending portion 43, the first tapered portion 411 and the second tapered portion 421 have gaps in an equal width between one another is formed.

The second parallel portion 422 extends from the second tapered portion 421 toward the side x1 along the first direction x. The second parallel portion 422 is formed in a region overlapping the first base portion 30 when viewing along the second direction y. In the example shown in the drawings, the size of the second parallel portion 422 along the second direction y is fixed.

The connecting portion 46 is located on the side x1 along the first direction x with respect to the first base portion 30 of the first electrode layer 3, and connects ends of the first parallel portion 412 and the second parallel portion 422 on the side x1 along the first direction x. The connecting portion 46 is not defined with a specific shape, and has an equal-width strip shape extending along the second direction y in the example shown in the drawings.

In this embodiment, three sides (the side x1 along the first direction x and two sides along the second direction y) of the first base portion 30 forming the first electrode layer 3 are surrounded by the connecting portion 46, the first parallel portion 412 and the second parallel portion 422 of the second electrode layer 4.

### Insulation Layer 5

As shown in FIG. 3 to FIG. 9, the insulation layer 5 is stacked on the first electrode layer 3 and the second electrode layer 4, and covers the first electrode layer 3 and the second electrode layer 4. The insulation layer 5 is not defined with a specific configuration, and can be, for example, a layered structure including a passivation film stacked on the first electrode layer 3 and the second electrode layer 4 and a resin film stacked on the passivation film. The passivation film can include, for example, a silicon nitride (SiN) layer. The resin film can include, for example, a polyimide resin.

The insulation layer 5 has a first opening portion 51 and a second opening portion 52. The first opening portion 51 passes through the insulation layer 5 along the thickness direction z, and overlaps the first base portion 30 of the first electrode layer 3 and the first external terminal 6 when viewing along the thickness direction z. The second opening portion 52 passes through the insulation layer 5 along the thickness direction z, and overlaps the second base portion 40 of the second electrode layer 4 and the second external terminal 7 when viewing along the thickness direction z.

Moreover, the insulation layer 5 can include a main surface insulation layer (omitted from the drawings) between the main surface 20 and a portion of the first electrode layer 3 and between the main surface 20 and a portion of the second electrode layer 4. The main surface insulation layer is not defined with a specific configuration, and can include, for example, a silicon oxide film formed on the main surface 20 and an undoped silica glass (USG) film stacked on the silicon oxide film. An opening for the first electrode layer 3 and the region 21 of the first conductivity type to come into contact, and an opening for the second electrode layer 4 and the impurity region 22 of the first conductivity type to come into contact are appropriately formed at the main insulation layer.

Herein, the Schottky carrier diode A1 has a back surface 91, a side surface 92, a side surface 93, an end surface 94 and an end surface 95. The back surface 91 is formed by the semiconductor substrate 1 of the first conductivity type, and is a surface facing the side z2 along the thickness direction z. The side surface 92, the side surface 93, the end surface 94 and the end surface 95 are formed by the semiconductor substrate 1 of the first conductivity type, the semiconductor layer 2 of the first conductivity type, and the insulation layer 5. The side surface 92 is a surface facing the side y1 along the second direction y. The side surface 93 is a surface facing the side y2 along the second direction y. The end surface 94 is a surface facing the side x1 along the first direction x. The end surface 95 is a surface facing the side x2 along the first direction x. Moreover, the side surface 92, the side surface 93, the end surface 94 and the end surface 95 can be configured to be exposed to the outside, or be configured to be covered by an oxide film. When the surfaces above are configured to be covered by an oxide film, if the thickness of the oxide film is configured to change gradually along the thickness direction z, the side surface 92, the side surface 93, the end surface 94 and the end surface 95 can appear in the colors of a rainbow.

### First External Terminal 6

The first external terminal 6 is a part used to electrically connect or mechanically connect the Schottky barrier diode A1 to the outside. In this embodiment, the first external terminal 6 is configured to be an anode terminal. The first external terminal 6 is not defined with a specific configuration, and can be, for example, a layered structured including multiple stacked metal films. The multiple metal films can include a Ni film, a Pd film and an Au (gold) film sequentially stacked from the side z2 along the thickness direction z.

In this embodiment, the first external terminal 6 has a first mounting portion 61 and a first connecting portion 62. The first mounting portion 61 is located on the side z1 along the thickness direction z with respect to the insulation layer 5. The first external terminal 6 is not defined with specific position, shape and size, and has a shape having two sides along two sides of the first direction x and along the second direction y in the example shown in the drawings, for example, a rectangle. Moreover, the first mounting portion 61 is located on the side x1 along the first direction x when viewing along the thickness direction z.

The first connecting portion 62 is embedded into the first opening portion 51 of the insulation layer 5, and is in contact with the first base portion 30 of the first electrode layer 3 via the first opening portion 51.

### Second External Terminal 7

The second external terminal 7 is a part used to electrically connect or mechanically connect the Schottky barrier diode A1 to the outside. In this embodiment, the second external terminal 7 is configured to be a cathode terminal. The second external terminal 7 is not defined with a specific configuration, and can be, for example, a layered structured including multiple stacked metal films. The multiple metal films can include a Ni film, a Pd film and an Au film sequentially stacked from the side z2 along the thickness direction z.

In this embodiment, the second external terminal 7 has a second mounting portion 71 and a second connecting portion 72. The second mounting portion 71 is located on the side z1 along the thickness direction z with respect to the insulation layer 5. The second external terminal 7 is not defined with specific position, shape and size, and has a shape having two sides along two sides of the first direction x and along the second direction y in the example shown in the drawings. Moreover, as shown in FIG. 2 and FIG. 3, the second external terminal 7 can also have a shape having a sloped side located on the side x2 along the first direction x and on the side y2 along the second direction y. Moreover, the second mounting portion 71 is located on the side x2 along the first direction x when viewing along the thickness direction z. That is to say, the first mounting portion 61 (first external terminal 6) and the second mounting portion 71 (second external terminal 7) are arranged along the first direction x.

The second connecting portion 72 is embedded into the second opening portion 52 of the insulation layer 5, and is in contact with the second base portion 40 of the second electrode layer 4 via the second opening portion 52.

As such, in the Schottky barrier diode A1, a current path connecting the first external terminal 6, the first electrode layer 3, the region 21 of the first conductivity type, the semiconductor substrate 1 of the first conductivity type, the impurity region 22 of the first conductivity type, the second electrode layer 4 and the second external terminal 7 is formed.

Next, functions of the Schottky barrier diode A1 are described below.

When a current flows from the first external terminal 6 to the second external terminal 7 via the first electrode layer 3, the region 21 of the first conductivity type and the semiconductor substrate 1 of the first conductivity type, the current flows through a conduction path with the lowest resistance among conduction paths flowing from the semiconductor substrate 1 of the first conductivity type to the second electrode layer 4 via the impurity region 22 of the first conductivity type. Because the first external terminal 6 is a part having a size (area) when viewing along the thickness direction z, the current may flow through a conduction path including a relatively long portion of the second electrode layer 4 according to the part of the first external terminal 6. For example, in FIG. 3, a conduction path from the impurity region 22 of the first conductivity type through the connecting portion 46, the first lateral extending portion 41 (or the second lateral extending portion 42) and the second base portion 40 to the second external terminal 7 is a longer path. According to this embodiment, the second electrode layer 4 has the third extending portion 43. The third extending portion 43 extends from the second base portion 40 toward the side x1 along the first direction x, and is located between the first extending region 31 and the second extending region 32 along the second direction y. Thus, a conduction path bypassing such as the connecting portion 46 can be replaced, such that a current flows in a conduction path from the third extending portion 43 via the second base portion 40 to the second external terminal 7. Accordingly, a conduction path can be shortened to reduce forward voltage.

As shown in FIG. 3, the size of each of the first extending portion 31 and the second extending portion 32 has a tapered shape that becomes smaller along the second direction y when further away from the first base portion 30 along the first direction x (closer to the side x2 from the side x1), and the size of the third extending portion 43 has a tapered shape that becomes smaller along the second direction y when further away from the second base portion 40 (closer to the side x1 from the side x2) along the first direction x. A current flowing through the third extending portion 43 flows from the side x1 to the side x2 along the first direction x. Thus, a current value gets higher as a part in the third extending portion 43 gets closer to the side x2 along the first direction x. The size of the third extending portion 43 becomes larger along the second direction y when closer to the side x2, and so an overly high current density can be inhibited.

The width W430 of the third end edge 430 is less than the width W310 of the first end edge 310 and the width W320 of the second end edge 320. Thus, a situation that an area of the first electrode layer 3 (the first extending portion 31 and the second extending portion 32) cannot be fully ensured due to an overly large width W430 can be prevented.

With the first lateral extending portion 41, the second lateral extending portion 42 and the connecting portion 46 included in the second electrode layer 4, more diversified conduction paths can be formed as conduction paths from the first external terminal 6 to the second external terminal 7, hence facilitating the reduction of forward voltage. With the first tapered portion 411 of the first lateral extending portion 41 and the second tapered portion 421 of the second lateral extending portion 42, an overly high current density can be inhibited.

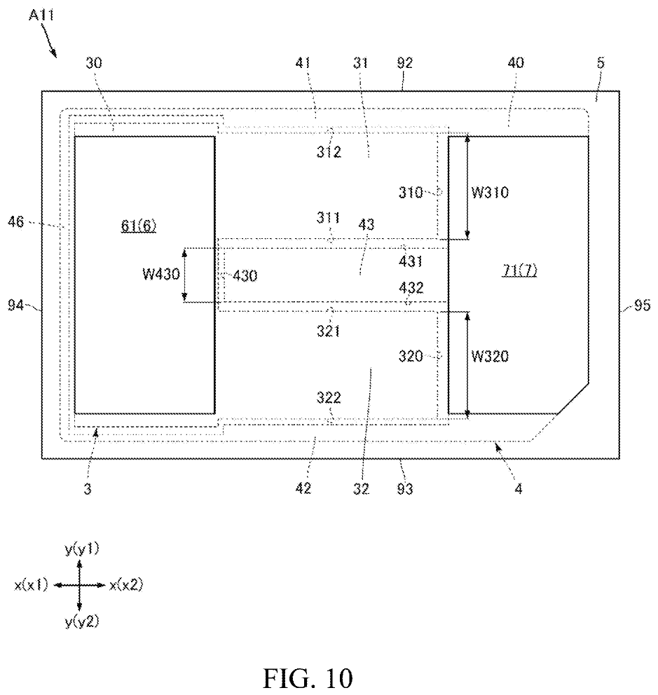

FIG. 10 to FIG. 15 show other embodiments of the present disclosure. Moreover, in these drawings, elements that are the same or similar to those of the embodiment above are assigned with the same denotations or numerals. Moreover, the configurations of various parts of the variation examples and the embodiments can be implemented in combination, given that they are not technically contradictory.

### First Variation Example of First Embodiment

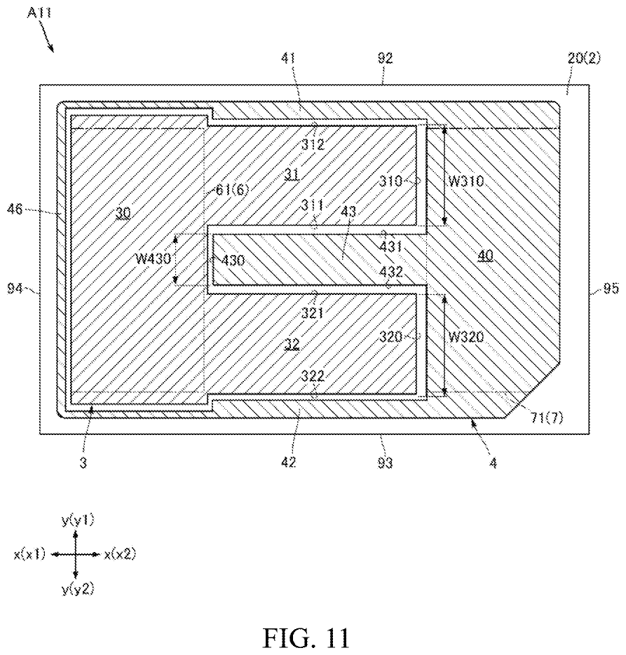

FIG. 10 and FIG. 11 show a first variation example of the Schottky barrier diode A1. The first extending portion 31, the second extending portion 32, the third extending portion 43, the first lateral extending portion 41 and the second lateral extending portion 42 of a Schottky barrier diode A11 of this variation example have shapes different from those of the embodiments described above.

In this variation example, the first side edge 311, the second side edge 312, the third side edge 321, the fourth side edge 322, the fifth side edge 431, the sixth side edge 423 are parallel with respect to the first direction x. Moreover, the sizes of the first lateral extending portion 41 and the second lateral extending portion 42 along the second direction y are fixed throughout the entire length along the first direction x.

Moreover, this variation example can also be configured such that the width W430 is less than the width W310 and the width W320.

Forward voltage can also be reduced according to this variation example. Moreover, as it can be understood from this variation example, the shapes of the first extending portion 31, the second extending portion 32, the third extending portion 43, the first lateral extending portion 41 and the second lateral extending portion 42 can also be appropriately set.

### Second Variation Example of First Embodiment

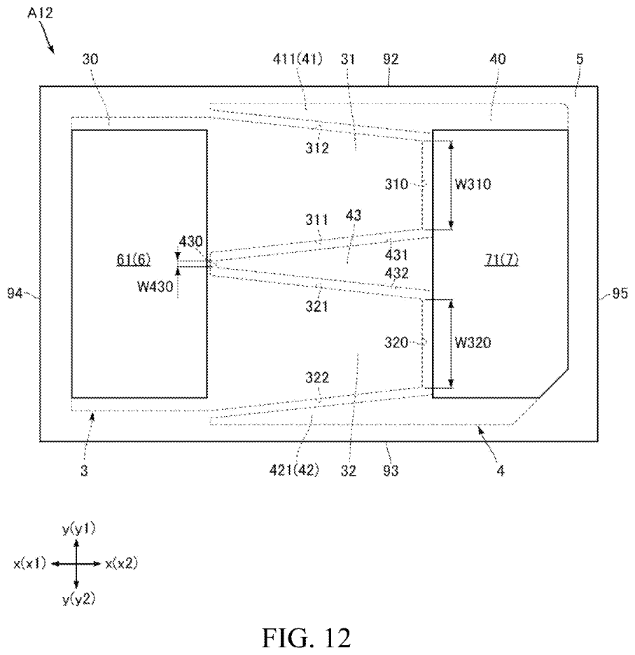

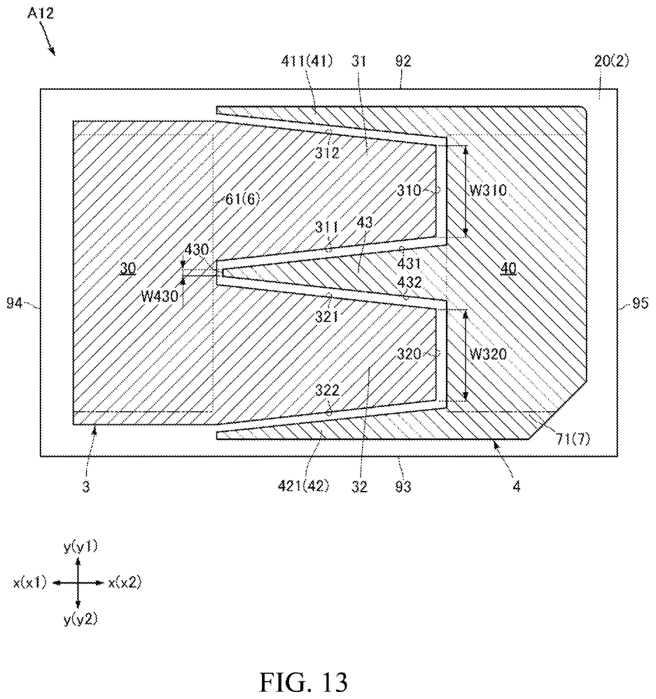

FIG. 12 and FIG. 13 show a second variation example of the Schottky barrier diode A1. The second electrode layer 4 of a Schottky barrier diode A12 of this variation example has a configuration different from that given in the above example.

In this variation example, the second electrode layer 4 does not have the connecting portion 46. That is to say, the first lateral extending portion 41 and the second lateral extending portion 42 are not configured to be connected by the first base portion 30 on the side x1 along the first direction x. Moreover, the first lateral extending portion 41 does not have the first parallel portion 412 but has the first tapered portion 411, and the second lateral extending portion 42 does not have the second parallel portion 422 but has the second tapered portion 421.

Forward voltage can also be reduced according to this variation example. Moreover, as it can be understood from this variation example, the specific configuration of the second electrode layer 4 can be appropriately set.

### Second Embodiment

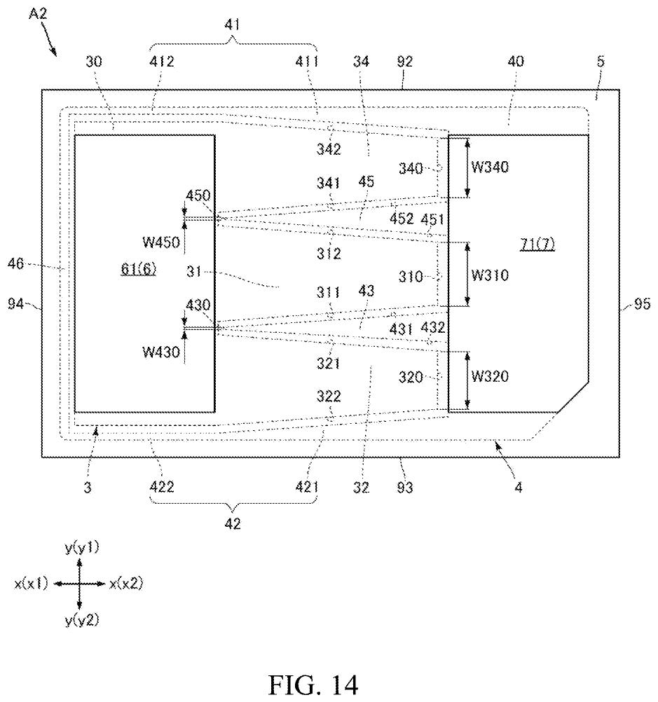

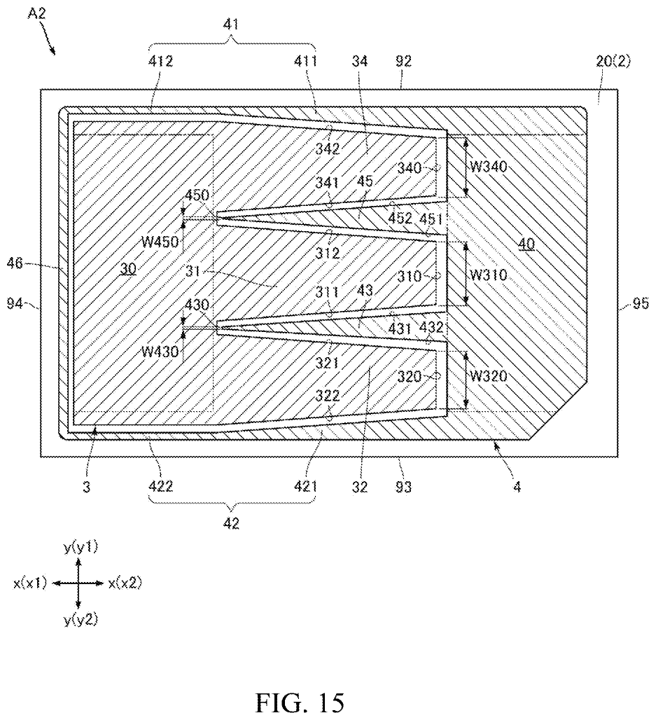

FIG. 14 and FIG. 15 show a Schottky barrier diode according to a second embodiment of the present disclosure. The first electrode layer 3 and the second electrode layer 4 of a Schottky barrier diode A2 of this embodiment have configurations different from those given in the above embodiment.

The first electrode layer 3 of this embodiment further has a fourth extending portion 34. The fourth extending portion 34 extends from the first base portion 30 toward the side x2 along the first direction x. The fourth extending portion 34 is not defined with a specific size, and can have a size of, for example, 150 μm or more and 800 μm or less, along the first direction x. In the example shown in the drawings, the fourth extending portion 34 is located on the side y1 along the second direction y with respect to the first extending portion 31. The fourth extending portion 34 has a fourth end edge 340, a seventh side edge 341 and an eighth side edge 342.

The fourth end edge 340 is an end edge on the side x2 along the first direction x. In the example shown in the drawings, the fourth end edge 340 is a straight line along the second direction y. The fourth end edge 340 is opposite to the second base portion 40 of the second electrode layer 4. The seventh side edge 341 is a side edge on the side y2 along the second direction y. The eighth side edge 342 is a side edge on the side y1 along the second direction y.

The fourth extending portion 34 is not defined with a specific shape, and in the example shown in the drawings, has a tapered shape that becomes smaller as a distance between the seventh side edge 341 and the eighth side edge 342 along the second direction y becomes smaller when further away from the first base portion 30 along the first direction x (closer to the side x2 from the side x1). The seventh side edge 341 and the eighth side edge 342 are inclined with respect to the first direction x. The angle of inclination of the seventh side edge 341 and the eighth side edge 342 can be 1° or more and 10° or less.

The second electrode layer 4 of this embodiment further has a fifth extending portion 45. The fifth extending portion 45 extends from the second base portion 40 toward the side x1 along the first direction x. The fifth extending portion 45 is not defined with a specific size, and can have a size of, for example, 150 μm or more and 800 μm or less, along the first direction x. The fifth extending portion 45 is located between the first extending portion 31 and the fourth extending portion 34 along the second direction y. The fifth extending portion 45 has a fifth end edge 450, a ninth side edge 451 and a tenth side edge 452.

The fifth end edge 450 is an end edge on the side x1 along the first direction x. In the example shown in the drawings, the fifth end edge 450 is a straight line along the second direction y. The fifth end edge 450 is opposite to the first base portion 30 of the first electrode layer 3. The ninth side edge 451 is a side edge on the side y2 along the second direction y, and is opposite to the second side edge 312. The tenth side edge 452 is a side edge on the side y1 along the second direction y, and is opposite to the seventh side edge 341.

The fifth extending portion 45 is not defined with a specific shape, and in the example shown in the drawings, has a tapered shape that becomes smaller as a distance between the ninth side edge 451 and the tenth side edge 452 along the second direction y becomes smaller when further away from the second base portion 40 along the first direction x (closer to the side x1 from the side x2). The ninth side edge 451 and the tenth side edge 452 are inclined with respect to the first direction x. The angle of inclination of the ninth side edge 451 and the tenth side edge 452 can be 1° or more and 10° or less.

In this embodiment, a width W450 which is the size of the fifth end edge 450 along the second direction y is less than the width W310, the width W320 and a width W340 which is the size of the fourth end edge 340 along the second direction y. The width W430 can be between 1 μm or more and 220 μm or less. The width W340 can be between 70 μm or more and 330 μm or less.

Forward voltage can also be reduced according to this embodiment. Moreover, as it can be understood from this embodiment, in addition to the first extending portion 31 and the second extending portion 32, the first electrode layer 3 can be configured to further include more than one extending portion represented by the fourth extending portion 34. Moreover, in addition to the third extending portion 43, the second electrode layer 4 can be configured to further include an extending portion represented by the fifth extending portion 45. The number of extending portions of each of the first electrode layer 3 and the second electrode layer 4 is appropriately set based on the overall sizes of the first electrode layer 3 and the second electrode layer 3 or effectiveness in reducing forward voltage.

The Schottky barrier diode of the present disclosure is not limited to the embodiments described above. Various design modifications may be made as desired to the specific configurations of various parts of the Schottky barrier diode of the present disclosure.

### Note 1

A Schottky barrier diode, comprising:
a semiconductor substrate of a first conductivity type;
a semiconductor layer of the first conductivity type, stacked on the semiconductor substrate of the first conductivity type, including a region of the first conductivity type and an impurity region of the first conductivity type, and having a main surface facing away the semiconductor substrate of the first conductivity type along a thickness direction;
a first electrode layer, formed on the main surface and forming a Schottky junction with the region of the first conductivity type;
a second electrode layer, formed on the main surface and forming an ohmic contact with the impurity region of the first conductivity type;
a first external terminal, electrically connected to the first electrode layer; and
a second external terminal, electrically connected to the second electrode layer, wherein in a first direction perpendicular to the thickness direction, the first external terminal is located on a first side, and the second external terminal is located on a second side,
the first electrode layer includes:
   a first base portion, overlapping the first external terminal when viewing along the thickness direction; and
      a first extending portion located on the first side and a second extending portion located on the second side along the thickness direction and a second direction perpendicular to the first direction, wherein each of the first extending portion and the second extending portion extends from the first base portion toward the second side along the first direction, and
the second electrode layer includes:
   a second base portion, overlapping the second external terminal when viewing along the thickness direction; and
   a third extending portion extending from the second base portion toward the first side along the first direction and located between the first extending portion and the second extending portion along the second direction.

### Note 2

The Schottky barrier diode of Note 1, wherein the first extending portion has a first side edge located on a second side of the second direction and a second side edge located on a first side of the second direction.

### Note 3

The Schottky barrier diode of Note 2, wherein further away from the first base portion along the first direction, a distance between the first side edge and the second side edge along the second direction becomes smaller.

### Note 4

The Schottky barrier diode of Note 2 or 3, wherein the first extending portion has a first end edge located on the second side along the first direction.

### Note 5

The Schottky barrier diode of Note 4, wherein the second extending portion has a third side edge located on the first side along the second direction and a fourth side edge located on the second side along the second direction.

### Note 6

The Schottky barrier diode of Note 5, wherein further away from the first base portion along the first direction, a distance between the third side edge and the fourth side edge along the second direction becomes smaller.

### Note 7

The Schottky barrier diode of Note 5 or 6, wherein the second extending portion has a second end edge located on the second side along the first direction.

### Note 8

The Schottky barrier diode of Note 7, wherein the third extending portion has a fifth side edge located on the first side along the second direction and a sixth side edge located on the second side along the second direction.

### Note 9

The Schottky barrier diode of Note 8, wherein further away from the second base portion along the first direction, a distance between the fifth side edge and the sixth side edge along the second direction becomes smaller.

### Note 10

The Schottky barrier diode of Note 8 or 9, wherein the third extending portion has a third end edge located on the first side along the first direction.

### Note 11

The Schottky barrier diode of Note 10, wherein a size of the third end edge along the second direction is less than a size of the first end edge and the second end edge along the second direction.

### Note 12

The Schottky barrier diode of any one of Notes 1 to 11, wherein the second electrode layer further includes:
a first lateral extending portion, located on the first side along the second direction with respect to the first extending portion and extending from the second base portion toward the first side along the first direction; and
a second lateral extending portion, located on the second side along the second direction with respect to the first extending portion and extending from the second base portion toward the first side along the first direction.

### Note 13

The Schottky barrier diode of Note 12, wherein the first lateral extending portion includes a first tapered portion having a size along the second direction becoming smaller away from the second base portion along the first direction, and the second lateral extending portion includes a second tapered portion having a size along the second direction becoming smaller away from the second base portion along the first direction.

### Note 14

The Schottky barrier diode of Note 12 or 13, wherein the second electrode layer further includes a connecting portion located on the first side along the first direction with respect to the first electrode layer and connecting the first lateral extending portion and the second lateral extending portion.

### Note 15

The Schottky barrier diode of any one of Notes 1 to 14, wherein the first electrode layer further includes a fourth extending portion extending from the first base portion to the second side along the first direction and located on the first side with respect to the first extending portion along the second direction, and the second electrode layer further includes a fifth extending portion extending from the second base portion to the first side along the first direction and located between the first extending portion and the third extending portion along the second direction.

### Note 16

The Schottky barrier diode of Note 15, wherein the fourth extending portion has a seventh side edge located on the second side along the second direction and an eighth side edge located on the first side along the second direction, and a distance between the seventh side edge and the eighth side edge along the second direction becomes smaller away from the first base portion along the first direction.

### Note 17

The Schottky barrier diode of Note 15 or 16, wherein the fifth extending portion has a ninth side edge located on the second side along the second direction and a tenth side edge located on the first side along the second direction, and a distance between the ninth side edge and the tenth side edge along the second direction becomes smaller away from the second base portion along the first direction.

1. A Schottky barrier diode, comprising:
a semiconductor substrate of a first conductivity type;
a semiconductor layer of the first conductivity type,
stacked on the semiconductor substrate of the first conductivity type,
including a region of the first conductivity type and an impurity region of the first conductivity type, and
having a main surface facing away the semiconductor substrate of the first conductivity type along a thickness direction;
a first electrode layer, formed on the main surface and forming a Schottky junction with the region of the first conductivity type;
a second electrode layer, formed on the main surface and forming an ohmic contact with the impurity region of the first conductivity type;
a first external terminal, electrically connected to the first electrode layer; and
a second external terminal, electrically connected to the second electrode layer, wherein
in a first direction perpendicular to the thickness direction, the first external terminal is located on a first side, and the second external terminal is located on a second side,
the first electrode layer includes:
a first base portion, overlapping the first external terminal when viewing along the thickness direction; and
a first extending portion located on the first side and a second extending portion located on the second side along the thickness direction and a second direction perpendicular to the first direction, wherein each of the first extending portion and the second extending portion extends from the first base portion toward the second side along the first direction, and
the second electrode layer includes:
a second base portion, overlapping the second external terminal when viewing along the thickness direction; and
a third extending portion extending from the second base portion toward the first side along the first direction and located between the first extending portion and the second extending portion along the second direction.

2. The Schottky barrier diode of claim 1, wherein the first extending portion has a first side edge located on a second side of the second direction and a second side edge located on a first side of the second direction.

3. The Schottky barrier diode of claim 2, wherein further away from the first base portion along the first direction, a distance between the first side edge and the second side edge along the second direction becomes smaller.

4. The Schottky barrier diode of claim 2, wherein the first extending portion has a first end edge located on the second side along the first direction.

5. The Schottky barrier diode of claim 4, wherein the second extending portion has a third side edge located on the first side along the second direction and a fourth side edge located on the second side along the second direction.

6. The Schottky barrier diode of claim 5, wherein further away from the first base portion along the first direction, a distance between the third side edge and the fourth side edge along the second direction becomes smaller.

7. The Schottky barrier diode of claim 5, wherein the second extending portion has a second end edge located on the second side along the first direction.

8. The Schottky barrier diode of claim 7, wherein the third extending portion has a fifth side edge located on the first side along the second direction and a sixth side edge located on the second side along the second direction.

9. The Schottky barrier diode of claim 8, wherein further away from the second base portion along the first direction, a distance between the fifth side edge and the sixth side edge along the second direction becomes smaller.

10. The Schottky barrier diode of claim 8, wherein the third extending portion has a third end edge located on the first side along the first direction.

11. The Schottky barrier diode of claim 10, wherein a size of the third end edge along the second direction is less than a size of the first end edge and the second end edge along the second direction.

12. The Schottky barrier diode of claim 1, wherein the second electrode layer further includes:
a first lateral extending portion, located on the first side along the second direction with respect to the first extending portion and extending from the second base portion toward the first side along the first direction; and
a second lateral extending portion, located on the second side along the second direction with respect to the first extending portion and extending from the second base portion toward the first side along the first direction.

13. The Schottky barrier diode of claim 2, wherein the second electrode layer further includes:
a first lateral extending portion, located on the first side along the second direction with respect to the first extending portion and extending from the second base portion toward the first side along the first direction; and
a second lateral extending portion, located on the second side along the second direction with respect to the first extending portion and extending from the second base portion toward the first side along the first direction.

14. The Schottky barrier diode of claim 3, wherein the second electrode layer further includes:
a first lateral extending portion, located on the first side along the second direction with respect to the first extending portion and extending from the second base portion toward the first side along the first direction; and
a second lateral extending portion, located on the second side along the second direction with respect to the first extending portion and extending from the second base portion toward the first side along the first direction.

15. The Schottky barrier diode of claim 12, wherein the first lateral extending portion includes a first tapered portion having a size along the second direction becoming smaller away from the second base portion along the first direction, and the second lateral extending portion includes a second tapered portion having a size along the second direction becoming smaller away from the second base portion along the first direction.

16. The Schottky barrier diode of claim 12, wherein the second electrode layer further includes a connecting portion located on the first side along the first direction with respect to the first electrode layer and connecting the first lateral extending portion and the second lateral extending portion.

17. The Schottky barrier diode of claim 1, wherein
the first electrode layer further includes a fourth extending portion extending from the first base portion to the second side along the first direction and located on the first side with respect to the first extending portion along the second direction, and
the second electrode layer further includes a fifth extending portion extending from the second base portion to the first side along the first direction and located between the first extending portion and the third extending portion along the second direction.

18. The Schottky barrier diode of claim 17, wherein
the fourth extending portion has a seventh side edge located on the second side along the second direction and an eighth side edge located on the first side along the second direction, and
a distance between the seventh side edge and the eighth side edge along the second direction becomes smaller away from the first base portion along the first direction.

19. The Schottky barrier diode of claim 17, wherein
the fifth extending portion has a ninth side edge located on the second side along the second direction and a tenth side edge located on the first side along the second direction, and
a distance between the ninth side edge and the tenth side edge along the second direction becomes smaller away from the second base portion along the first direction.

20. The Schottky barrier diode of claim 18, wherein
the fifth extending portion has a ninth side edge located on the second side along the second direction and a tenth side edge located on the first side along the second direction, and
a distance between the ninth side edge and the tenth side edge along the second direction becomes smaller away from the second base portion along the first direction.
